(19) United States
(12) Patent Application Publication
(10) Pub. No.: US 2006/0225998 A1
(43) Pub. Date: Oct. 12, 2006

(54) Direct ion beam deposition method and system

(76) Inventor: Seok Kyun Song, Seoul (KR)

Correspondence Address: PARK LAW FIRM, 3255 WILSHIRE BLVD, SUITE 1110, LOS ANGELES, CA, 90010, US

(21) Appl. No.: 11/131,825

(22) Filed: May 18, 2005

(30) Foreign Application Priority Data
Apr. 12, 2005 (KR) 10-2005-0030228

(51) Int. Cl. C23C 14/00

(52) U.S. Cl. 204/192.11; 204/298.04

(57) ABSTRACT

Disclosed herein is a direct ion beam deposition method through ion beam sputtering. The method comprises the steps of: a) providing a workpiece on which a certain material is to be deposited with a certain desired thickness; b) providing a deposit material having a certain area from which the deposit material is discharged into a certain working gas atmosphere; c) transforming the working gas atmosphere into a plasma atmosphere by bombarding electrons widely to the working gas atmosphere; d) emitting a surface material by means of a sputter from the deposit material exposed in the plasma atmosphere; e) exposing the emitted deposit material to an ionization environment; f) and providing energy to the deposit material by applying an electric potential to the step e) to thereby be radiated on a corresponding face of the workpiece. A direct ion beam deposition system is also disclosed.

The application claims and requests a foreign priority, through the Paris Convention for protection of Industrial Property, based on a patent application filed in the Republic of Korea with number 10-2005-0030228, by the applicant, the contents of which are incorporated by reference into this disclosure as if fully set forth herein.

### BACKGROUND OF THE INVENTION

1. Field of the Invention

The present invention relates to a direct ion beam deposition system. In particular, the invention relates to a direct ion beam deposition method and system through ion beam sputtering, in which a direct ion beam deposition mode and an ion beam sputtering deposition mode are combined to thereby enable a thin film deposition over a large-area under a low pressure by the direct ion beam deposition mode and simultaneously to enable a high quality thin film deposition.

2. Background of the Related Art

In general, the semiconductor processing techniques are fundamental to the manufacturing of a highly integrated memory, or an analogue or digital logic integrated circuit, and also can be applied directly to the manufacturing of various elements such as a micro-machine, a flat panel display or the like. Thus, its applications have been widely spread.

In the semiconductor and new materials industry, in particular, in the surface coating and sputtering technologies for manufacturing or depositing a thin film, the stable generation and control of plasma is essential to improvement in the production efficiency and yield therefor.

Thus, various systems have been developed and commercialized, including a CCP (capacitively coupled plasma), an ICP (inductively coupled plasma, an ECR (electron cyclotron resonance, a Helical apparatus, a Helicon apparatus, and the like. These systems have been continuously modified and improved in order to achieve uniform and high quality plasma, which leads directly to a high quality thin film.

General problems to be solved in the current typical thin film deposition techniques will be briefed below. First, the RF process has a limitation in its uniformity due to the non-uniform electromagnetic field, instability and inefficiency due to the matching to the expensive power supply equipment, interference with peripheral devices, and the high operating pressure of 10⁻³ to 10⁻² torr. Thus, the RF process has a limitation in manufacturing a high quality thin film.

In addition, the microwave process has a limitation in the large-area and inconvenient maintenance due to the high priced power supply and the service life of about 6,000 hours, and thus its application is very limited.

Furthermore, the MBE process capable of obtaining a high quality thin film has a limitation in the productivity thereof.

Therefore, recently a direct ion beam deposition process has been proposed in order to solve the above problems with the conventional techniques. This process can produce a very dense thin film of high quality.

Referring to the accompanying drawings, conventional direct ion beam processes will be hereafter briefed. FIG. 1 shows the HAD (hollow cathode arc activated deposition) process, which has been proposed by Fraunhofer Institute for Electron and Plasma Technology in Germany. A deposit material is evaporated through an electron gun and the vaporized material is ionized through a hollow cathode to thereby provide energy to the deposit material, which is vapor-deposited eventually.

FIG. 2 shows an example of vapor-deposition using the above ion beam process, i.e., an aluminum oxide film deposited on the iron substrate using the direct ion beam process.

Referring to FIG. 2, it can be seen that a dense thin film is formed by ion beam. As shown in the photograph of FIG. 2, the thin film is formed in a very dense form and has an improved surface roughness, in the case where the deposit material is ionized with electrons and then deposited on the substrate.

However, the above direct ion beam deposition technology embraces several problems.

The deposition process using an electron gun cannot easily achieve deposition for a large-area, has a limitation in the uniformity of deposition, has a low ionization rate, and cannot provide an adequate energy to ions to be deposited.

In order to solve the above problems, the Cs negative metal ion deposition system has been proposed by Plasmion, a U.S. company. FIG. 3 shows the Cs negative metal ion deposition system, in which a target material is sputtered by Cs ion and at the same time the surface energy thereof is lowered such that the material to be sputter is made negative and deposited by means of bias. It has been reported that various high-grade thin films can be formed through this process.

However, this has not been applied yet to a practical production process, due to difficulties in handling the metal cesium (Cs).

As described above, the conventional various vapor-deposition systems have both advantages and disadvantages. Accordingly, many attempts and studies have been continued in order to improve the conventional processes.

### SUMMARY OF THE INVENTION

Therefore, the present invention has been made in view of the above problems occurring in the prior art, and it is an object of the present invention to provide a direct ion beam deposition method and system through ion beam sputtering, in which a direct ion beam deposition mode and an ion beam sputtering deposition mode are combined to thereby enable a thin film deposition over a large-area under a low pressure by the direct ion beam deposition mode and simultaneously to enable a high quality thin film deposition.

To accomplish the above object, according to one aspect of the present invention, there is provided a direct ion beam deposition method through ion beam sputtering. The method of the invention includes the steps of: a) providing a workpiece on which a certain material is to be deposited with a certain desired thickness; b) providing a deposit material having a certain area from which the deposit material is discharged into a certain working gas atmosphere; c) transforming the working gas atmosphere into a plasma atmosphere by bombarding electrons widely to the working gas atmosphere; d) emitting a surface material by means of a sputter from the deposit material exposed in the plasma atmosphere; e) exposing the emitted deposit material to an ionization environment; f) and providing energy to the deposit material by applying an electric potential to the step e) to thereby be radiated on a corresponding face of the workpiece.

According to another aspect of the invention, there is provided with a direct ion beam deposition system using ion beam sputtering. The system includes: a) an electron emitter means for emitting initial electrons for ion beam generation within a certain operating pressure; b) an electron guide means for supplying a working gas for formation of plasma atmosphere and guiding into the working gas the electron flow generated from the electron emitter means; c) an upper case for fixing the position of the electron guide means; d) a deposit material having a certain area and disposed below the electron guide means, an exposed surface material of the deposit material being emitted and radiated in the form of ion when the working gas is transformed into a plasma atmosphere by charges guided by the electron emitter means and the electron guide means in a certain working gas atmosphere; e) a cooling means placed below the deposit material for preventing overheat of the deposit material; f) an electromagnetic field formation means placed below the cooling means for forming a certain magnitude of electromagnetic field such that electrons emitted from the electron emitter means is turned when guided by the electron guide means; g) a lower case disposed facing the upper case for fixing the position of the deposit material, the cooling means and the electromagnetic field formation means; and h) a power supply for retaining a certain magnitude of potential difference in the electron emitter means and the electron guide means and facilitating ion emission of the deposit material.

The electromagnetic field formation means may employ a magnet or an electromagnet.

The cooling means may include a cooling jacket in which cooling water is circulated.

The electron guide means is divided into a first anode for guiding the working gas onto the surface of the deposit material and for guiding electron flow emitted from the electron emitter means, and a second anode for guiding the electron flow emitted from the electron emitter means and forming an ionization region; generally placed in the lateral face of the exposed face of the deposit material in the form of a side wall; and constructed to make an angle parallel to the direction of electromagnetic field generated in the electromagnetic field formation means and have an anode angle θ such that the electrons emitted from the electron emitter means can reach evenly over the entire face of the lateral wall.

The electron guide means may be structured in the form of a rectangular frame or a circular frame.

The first anode includes: i) an upper portion having a first space into which a working gas is flown from outside; ii) an intermediate portion having a second space connected through a distribution hole for distributing the working gas flown into the firs space evenly over the whole area; and iii) a lower portion having a supply hole for discharging the working gas being filled in the second space.

The operating pressure of the system is usually in a range of 10⁻⁵˜10⁻³ Torr, and typically 10⁻⁴ Torr.

The electron emitter means may include a filament having a certain length and area.

The electron emitter means may have a desired spacing in a vertical direction to the centerline of the upper case and the lower case. A metal cathode case is provided with holes placed at desired regular intervals through which electrons are discharged along the centerline, and a filament for emitting thermal electrons is disposed inside the metallic cathode case filled with argon gas.

Alternatively, the electron emitter means may have a desired spacing in a vertical direction to the centerline of the upper case and the lower case. A metal cathode case is provided with holes placed at desired regular intervals through which electrons are discharged along the centerline, and a hollow cathode for emitting electrons is disposed inside the metallic cathode case filled with argon gas.

As another alternative, the electron emitter means may have a desired spacing in a vertical direction to the centerline of the upper case and the lower case. A metal cathode case is provided with holes placed at desired regular intervals through which electrons are discharged along the centerline, and an RF coil for emitting electrons is disposed inside the metallic cathode case filled with argon gas.

According to another aspect of the invention, there is provided with a direct ion beam deposition system using ion beam sputtering. The system includes: an electron emitter means for emitting initial electrons for ion beam generation within a certain operating pressure; an electron guide means for supplying a working gas for formation of plasma atmosphere and guiding into the working gas the electron flow generated from the electron emitter means; an upper case for fixing the position of the electron guide means; an electromagnetic field formation means placed in the outer periphery of the upper case for forming a certain magnitude of electromagnetic field such that electrons emitted from the electron emitter means is turned when guided by the electron guide means; a deposit material having a certain area and disposed below the electron guide means, an exposed surface material of the deposit material being emitted and radiated in the form of ion when the working gas is transformed into a plasma atmosphere by charges guided by the electron emitter means and the electron guide means in a certain working gas atmosphere; a cooling means placed below the deposit material for preventing overheat of the deposit material; a lower case disposed facing the upper case for fixing the position of the deposit material and the cooling means; and a power supply for retaining a certain magnitude of potential difference in the electron emitter means and the electron guide means and facilitating ion emission of the deposit material.

The electromagnetic field formation means may employ a magnet or an electromagnet.

The cooling means may include a cooling jacket in which cooling water is circulated.

The electron guide means is divided into a first anode for guiding the working gas onto the surface of the deposit material and for guiding electron flow emitted from the electron emitter means, and a second anode for guiding the electron flow emitted from the electron emitter means and forming an ionization region; generally placed in the lateral face of the exposed face of the deposit material in the form of a side wall; constructed to make an angle parallel to the direction of electromagnetic field generated in the electromagnetic field formation means and have an anode angle θ such that the electrons emitted from the electron emitter means can reach evenly over the entire face of the lateral wall; and structured such that the first anode has an area slightly larger than that of the second anode.

The electron guide means may be structured in the form of a rectangular frame or a circular frame.

The operating pressure of the system is usually in a range of 10⁻⁵˜10⁻³ Torr, and typically 10⁻⁴ Torr.

The electron emitter means may include a filament having a certain length and area.

The electron emitter means may have a desired spacing in a vertical direction to the centerline of the upper case and the lower case. A metal cathode case is provided with holes placed at desired regular intervals through which electrons are discharged along the centerline, and a filament for emitting thermal electrons is disposed inside the metallic cathode case filled with argon gas.

Alternatively, the electron emitter means may have a desired spacing in a vertical direction to the centerline of the upper case and the lower case. A metal cathode case is provided with holes placed at desired regular intervals through which electrons are discharged along the centerline, and a hollow cathode for emitting electrons is disposed inside the metallic cathode case filled with argon gas.

As another alternative, the electron emitter means may have a desired spacing in a vertical direction to the centerline of the upper case and the lower case. A metal cathode case is provided with holes placed at desired regular intervals through which electrons are discharged along the centerline, and an RF coil for emitting electrons is disposed inside the metallic cathode case filled with argon gas.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 is a schematic view explaining the HAD process which is one of conventional direct ion beam deposition technologies;

FIG. 2 is a photograph showing an effect of the conventional direct ion beam deposition process;

FIG. 3 is a schematic view showing the concept of the Cs negative metal ion deposition system, which has been recently proposed;

FIG. 4 is a schematic view of a direct ion beam deposition system through ion beam sputtering according to the invention;

FIG. 5 is a perspective view of part of the system in FIG. 4;

FIG. 6 shows the structure of an anode in the direct ion beam deposition system of the invention;

FIG. 7 is a sectional and perspective view of the structure of a first anode in FIGS. 4 to 6.

FIG. 8 is a schematic view of a direct ion beam deposition system according to another embodiment of the invention;

FIG. 9 is a schematic view of a modified cathode according to another embodiment of the invention;

FIG. 10 is a perspective view of the cathode in FIG. 9;

FIG. 11 shows a relationship with the power supply where the electron emitter employs a filament cathode;

FIG. 12 shows a relationship with the power supply where the electron emitter employs a hollow cathode;

FIG. 13 shows a relationship with the power supply where the electron emitter employs a RF cathode;

FIG. 14 is a graph showing a relation between the second anode current and the gas ion current density in the direct ion beam deposition system having a circular anode according to an embodiment of the invention; and

FIG. 15 is a graph showing the gas ion current density with the distance from beam axis in the direct ion beam deposition system having a circular anode according to an embodiment of the invention.

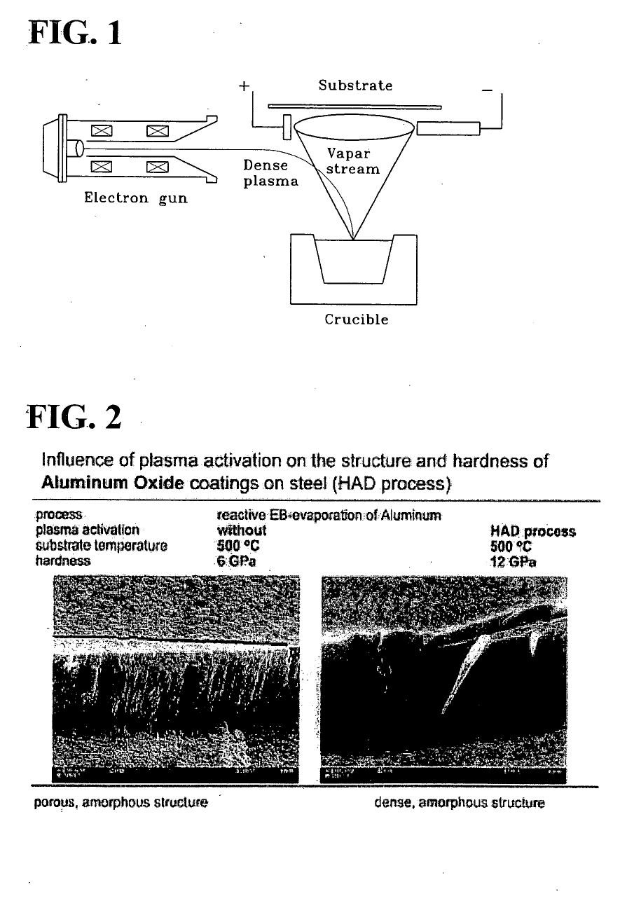

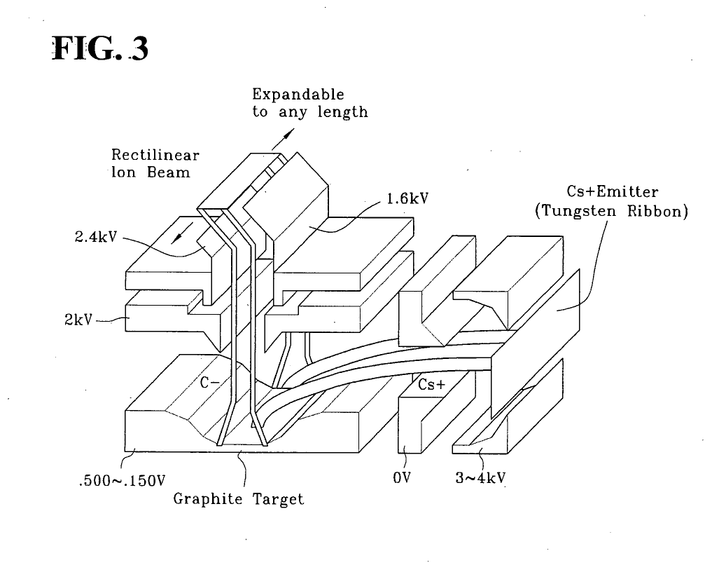

### DETAILED DESCRIPTION OF THE PREFERRED EMBODIMENT

The preferred embodiments of the invention will be hereafter described in detail, with reference to the accompanying drawings.

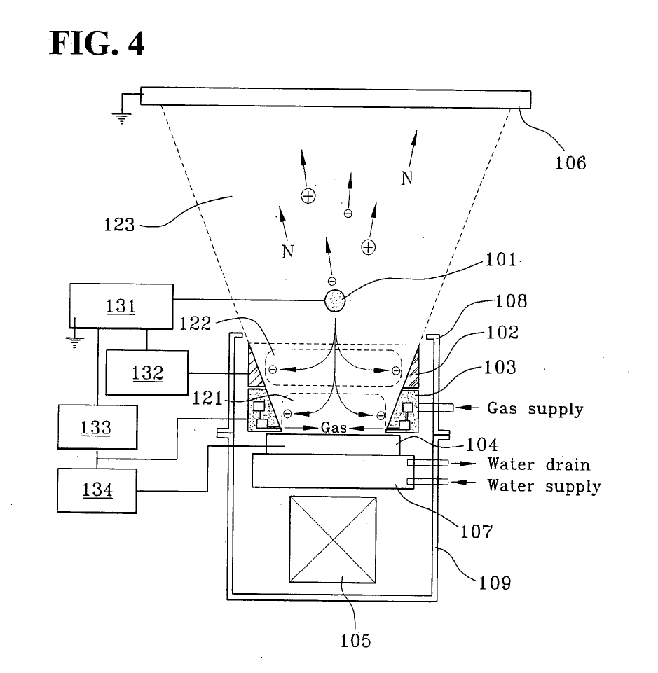

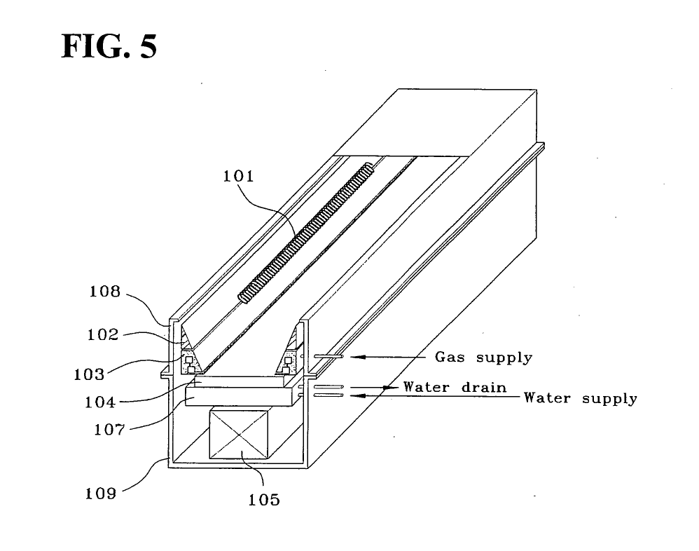

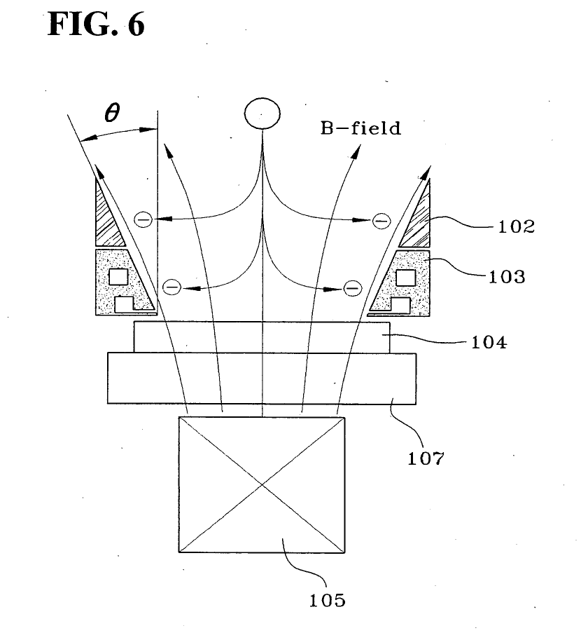

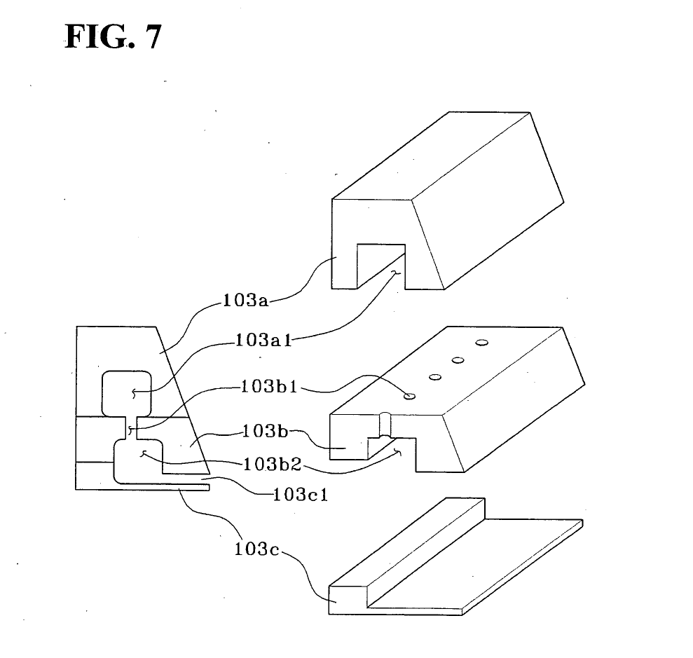

FIG. 4 is a schematic view of a direct ion beam deposition system through ion beam sputtering according to the invention. FIG. 5 is a perspective view of part of the system in FIG. 4. FIG. 6 shows the structure of an anode in the direct ion beam deposition system of the invention. FIG. 7 is a sectional and perspective view of the structure of a first anode in FIGS. 4 to 6, where the first anode is indicated by reference numeral 103.

Referring to FIGS. 4 to 7, the construction and operation of a direct ion beam deposition system through ion beam sputtering according to the invention will be described.

As illustrated in FIGS. 4 and 5, the direct ion beam deposition system through ion beam sputtering according to the invention includes a filament cathode 101 for generating initial charges to generate ion beam, an anode 102, 103 for guiding a charge flow generated from the filament cathode 101, an upper case 108 for adjusting the position of the anode 102, 103, a target 104 formed of a material (for example, aluminum) to be sputtered and deposited by means of charges, which are guided by the filament cathode 101 and the anode 102, 103, a target cooling jacket 107 disposed below the target 104 such that a cooling water is circulated therein to thereby prevent overheating of the target 104 by the sputtering, a magnet (electromagnet) 105 disposed below the target cooling jacket 107 and for forming a certain magnitude of electromagnetic field, and a lower case 109 facing the upper case 108 and for fixing the positions of the target 104, the target cooling jacket 107 and the magnet (electromagnet) 105.

Here, the anode 102, 103 is divided into a first anode 103 and a second anode 102. As shown in FIG. 7, the first anode 103 is composed of an upper part 103a having a first working gas space 103a1, an intermediate part 103b having a second working gas space 103b2 connected with the first working gas space 103a1 through a working gas distribution hole 103b1, and an lower part 103c having a working gas supply hole 103c1 for discharging the working gas filled in the second working gas space 103b2.

The working gas is flown into the first working gas space 103a1 and then distributed uniformly into the second working gas space 103b2 through the working gas distribution hole 103b1. Thereafter, the working gas is uniformly emitted through the working gas supply hole 103c1.

In addition, the first anode 103 may be formed in a rectangular or circular structure. That is, the first anode 103 and the second anode 102 have the form of a rectangular or a circle.

That is, as shown in FIG. 6, the first anode 103 and the second anode 102 is structured to have an anode angle θ such that the electromagnetic field generated from the magnet 105 can be reached evenly over the front face of the anode 102, 103 in parallel thereto. Accordingly, depending on the form of the substrate to be deposited thereon, the general shape of the anode is not restricted in particular, as long as the anode angle can be maintained.

Here, in FIG. 4, reference numbers 131 to 134 are power supplies for normal operation of the direct ion beam deposition system through ion beam sputtering according to the invention. The reference numeral 131 denotes a filament cathode power supply for heating the filament cathode 101, the numeral 132 denotes a second anode power supply for assigning a certain electric potential to the second anode 102, the numeral 133 denotes a first anode power supply for assigning a certain electric potential to the first anode 103.

Here, the anode power supplies 132 and 133 each is electrically connected to the filament cathode power supply 131.

In addition, a sputter power supply 134 for sputtering is connected to the target 104 and the first anode 103. At this time, a working gas is supplied to the first anode 103.

Here, the working gas employs all kinds of gas.

The operation of the direct ion beam deposition system according to an embodiment of the invention having the above construction will be hereafter described.

First, the working gas is flown into a plasma generation region 121 through the first anode 103 and the filament cathode 101 is heated by AC or DC current of the filament cathode power supply 131. At this state, DC electric powers are applied to the second anode 102 and the first anode 103 through the second anode power supply 132 and the first anode power supply 133, respectively, thereby generating of thermal electrons from the filament cathode 101.

The electron emitted from the cathode 101 flows into the second anode 102 and the first anode 103. At this time, as shown in FIG. 6, the electrons are supposed to flow along the shortest path, and thus the electrons flow down mostly along the central area by means of the electromagnetic field. Near the anodes, the electrons are directed into the anodes perpendicularly to the direction of electromagnetic field while doing a circular motion, during which the electrons are collided with gas to thereby ionize the gas.

That is, plasma is generated by each anode in both the ionization region 122 and the plasma generation region 121 for sputter.

At this time, if a DC, AC, pulse or RF voltage is applied to the first anode 103 and the target 104 through the sputter power supply 134, ions in the plasma, which is generated in the plasma generation region 121 for sputter, is collided into the target 104, thereby sputtering the target material.

The sputtered neutral particles are ionized into positive ions while passing upwardly the ionization region 122. The positive ion approaching the substrate 106 has an energy, which corresponds to the potential applied to the second anode 102 through the second anode power supply 132.

At this time, by means of the ions to be deposited, the cathode 101 emits almost the same number of electrons as the ions towards the substrate, which thereby is neutralized to eliminate the charge built-up therein.

Some neutral particles, which are not ionized, reach the substrate at the same time, but the energy of the energized ions is transferred to thereby form a high-graded thin film.

This is, the particles reaching the substrate 106 include energized ions emitted from the target 104, neutral particles, electrons, ionized working gas having an energy, neutral working gas. Among them, the deposition ions having an energy and the working gas having an energy are of importance in forming a high quality thin film.

In the above explanation, if the first anode power supply 133 and the sputter power supply 134 are not used, it becomes a hybrid ion source, which can be used with a gas ion source only.

The operating pressure of the invention is usually 10⁻⁵˜10⁻³ Torr, typically 10⁻⁴ Torr, and has the following advantages.

It is well known that a lower operating pressure leads to a higher quality of thin film. Usually, the operating pressure of a RF magnetron and a DC magnetron is 2×10⁻³˜10⁻¹ Torr. In the direct ion beam deposition system of the invention, the operating pressure is 10˜100 times lower, thereby forming a higher-grade thin film.

In addition, since the deposit material is directly ionized, it has a strong reactivity and energy, thereby forming a high quality thin film on a low temperature substrate.

In the present invention, the deposit material is sputtered by means of ion beam, and thus the sputtered neutral particle has a certain amount of energy and a direct ion beam deposition can be carried out in a large-area, which is the merit of sputtering.

In addition, the present invention provides a structure capable of maximizing the plasma generation efficiency while forming the electromagnetic field in a fixed one direction, thereby achieving a great degree of uniformity, which cannot be easily obtained in the conventional sputtering. That is, the consumption efficiency of target can be maximized through a uniform target sputtering, along with uniformity in the thickness and property of a resultant thin film.

The direct ion beam deposition system may change or modify its structure in various other ways. Hereafter, several modifications will be described, with reference to the accompanying drawings.

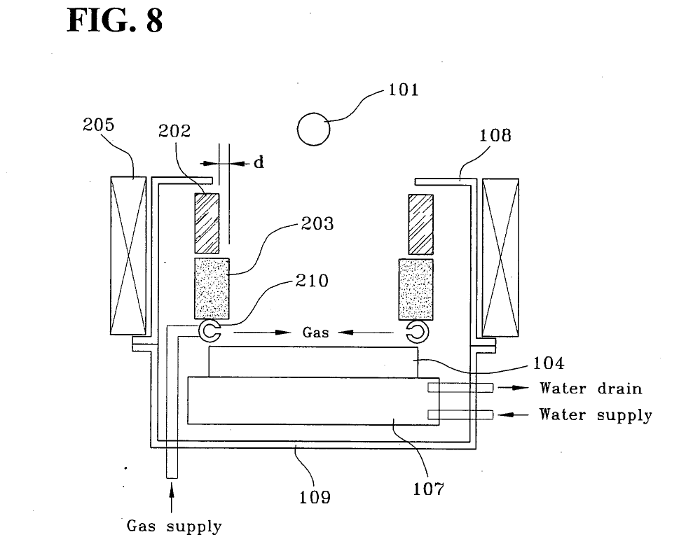

FIG. 8 illustrates a modified structure of the direct ion beam deposition system through direct beam sputtering according to a second embodiment of the invention.

In the second embodiment of FIG. 8, a magnet or electromagnet 205 is placed beside the anode and the anode is structured so as to be aligned with the direction of the electromagnetic field, i.e., substantially parallel thereto. The first anode 203 is slightly smaller by d than the second anode 202.

The second embodiment of FIG. 8 can be easily fabricated, as compared with the first embodiment illustrated in FIGS. 4 to 7, but has a smaller spread of ion beam and thus a smaller deposit area, relatively to the first embodiment. The second embodiment is operated in the same manner as in the first one.

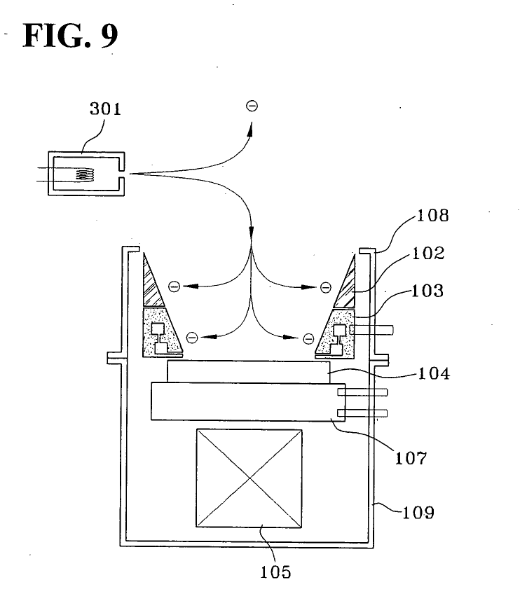

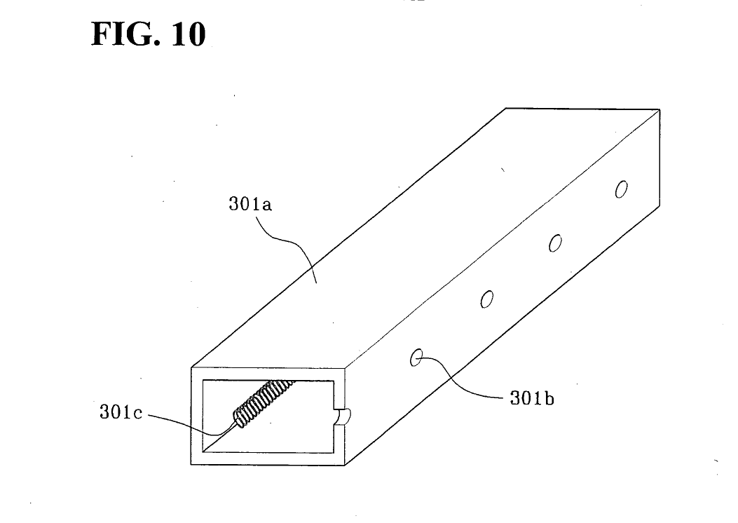

In addition, FIG. 9 illustrates a direct ion beam deposition system through ion beam sputtering according to a third embodiment, where the position of cathode is modified. FIG. 10 is a perspective view of the cathode in the third embodiment of FIG. 9.

FIG. 9 shows a modified cathode position, in which the cathode 301 is disposed right beside the direct ion beam region 123 through which ion beam passes.

The modified cathode of FIG. 10 has a rectangular shape, but may have a circular shape.

The modified cathode 301 has plural holes 302b formed in a metallic case 301a at regular intervals along the direct ion beam. Electrons are discharged through the holes 301b. Inside the modified cathode 301 is provided an electron emitter means (for example, a filament 301c of filament plasma cathode) within the cathode case 301a.

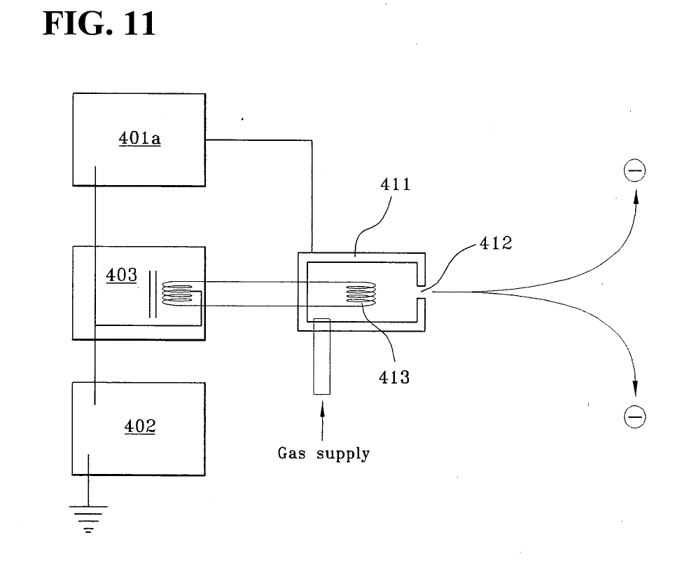

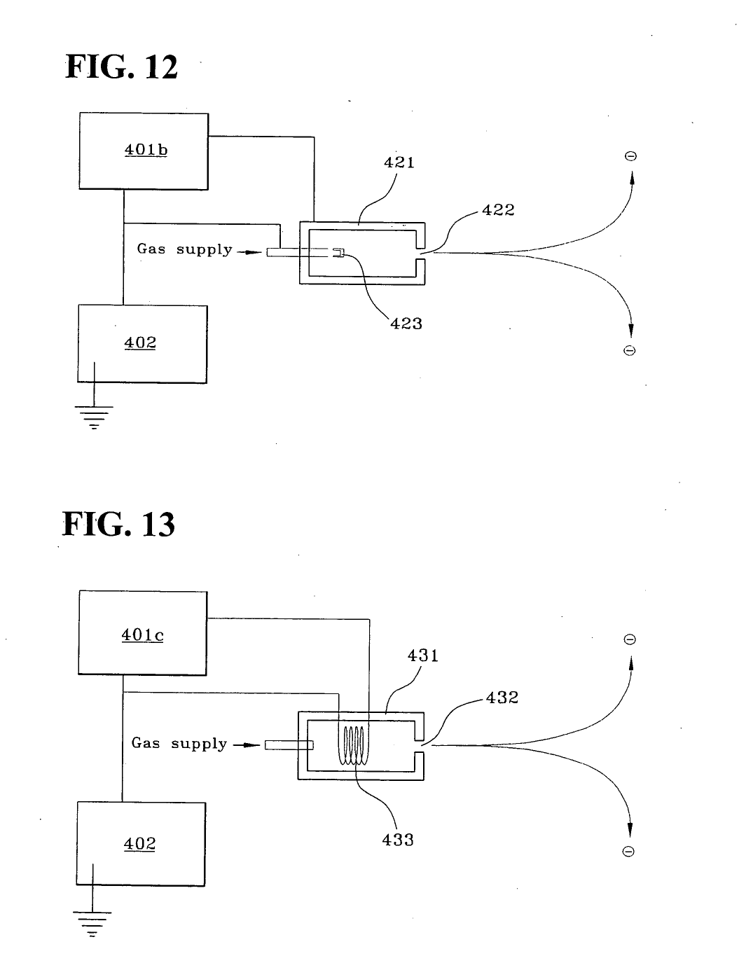

The electron emitter means provided inside the modified cathode of FIGS. 9 and 10 may be divided into several types, as shown in FIGS. 11 to 13. FIG. 11 shows a relationship with the power supply where the internal electron emitter means employs a filament plasma cathode. FIG. 12 shows a relationship with the power supply where the electron emitter means employs a hollow cathode. FIG. 13 shows a relationship with the power supply where the electron emitter means employs a RF cathode.

As illustrated in FIGS. 9 to 13, the modified cathode includes a filament plasma cathode (FIG. 11), a hollow cathode (FIG. 12), and a RF cathode (FIG. 13), the respective structure and operation of which will be described below.

Referring FIG. 11, in the case where the internal electron emitter of the modified cathode employs a filament plasma cathode, a relationship with the power supply is described. At the state where argon gas is injected inside the cathode case 411, an electric current is applied to the filament 413 through a filament power supply 403 and an electric voltage is applied through a plasma generation power supply 401a to the center tab of the filament power supply 403 and the cathode case 411, thereby generating plasma inside the cathode case 411.

At this time, the voltage of the electron emitter power supply 402 is applied to the center tab and earth of the filament power supply 403 such that electrons among the plasma generated inside the cathode case 411 is discharged to outside through a cathode hole 412.

Referring FIG. 12, in the case where the internal electron emitter means employs a hollow cathode, a relationship with the power supply is described. At the state where argon gas is injected inside the cathode case 421, the voltage of the plasma generation power supply 401b is applied to the anode 423 of the hollow cathode and the cathode case 421 to thereby generate plasma inside the cathode case 421.

At this time, the voltage of the electron emitter power supply 402 is applied to the anode 423 of the hollow cathode and the earth such that electrons among the plasma generated inside the cathode case 421 is discharged to outside through a cathode hole 422.

Referring FIG. 13, in the case where the internal electron emitter means employs a RF cathode, a relationship with the power supply is described. At the state where argon gas is injected inside the cathode case 431, the voltage of the RF plasma generation power supply 401c is applied to the RF coil 433 to thereby generate plasma inside the cathode case 431.

At this time, the voltage of the electron emitter power supply 402 is applied to the RF coil 433 and the earth such that electrons among the plasma generated inside the cathode case 431 is discharged to outside through a cathode hole 432.

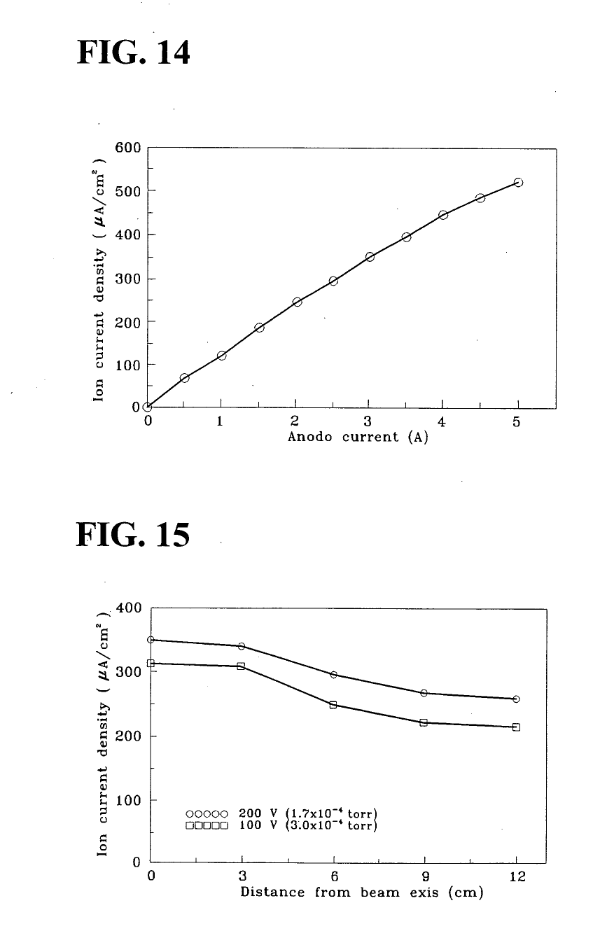

FIG. 14 is a graph showing a relation between the second anode current and the gas ion current density in the direct ion beam deposition system having a circular anode according to an embodiment of the invention. It can be seen from the graph that the ion current density is improved to 500 μA/cm², which is more than 10 times of a conventional ion source, i.e., several tens μA/cm².

FIG. 15 is a graph showing the gas ion current density with the distance from beam axis in the direct ion beam deposition system having a circular anode according to an embodiment of the invention. It can be seen from the graph that the ion beam is widely diverged over a large-area, where the diameter of the circular anode is 4 cm.

The ion beam is widely diverged over a large-area, due to the Hall effect. That is, the ion beam is spread trough the anode having a circular structure and the electromagnetic field, which is directed upward in a vertical direction and then spread. The circular anode provides a widely spread ion beam, but the uniformity thereof is slightly degraded. The rectangular structure anode can achieve a uniform ion beam over a large-area.

As described above, according to the direct ion beam deposition method and system using ion beam sputtering, an ion beam sputter is employed as the plasma ion source, and thus a high-grade thin film can be formed at a low operating pressure of below 10⁻⁴ Torr. The energy of deposit ion can be adjusted to 1500 eV, and a high density of ion beam current can be achieved up to above 500 μA/cm², thereby enabling to form a high-grade thin film with a high deposition rate.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A direct ion beam deposition method through ion beam sputtering, the method comprising steps of:
a) providing a workpiece on which a certain material is to be deposited with a certain desired thickness;
b) providing a deposit material having a certain area from which the deposit material is discharged into a certain working gas atmosphere;
c) transforming the working gas atmosphere into a plasma atmosphere by bombarding electrons widely to the working gas atmosphere;
d) emitting a surface material by means of a sputter from the deposit material exposed in the plasma atmosphere;
e) exposing the emitted deposit material to an ionization environment; and
f) providing energy to the deposit material by applying an electric potential to the step e) to thereby be radiated on a corresponding face of the workpiece.

2. A direct ion beam deposition system using ion beam sputtering, the system comprising:
a) an electron emitter means for emitting initial electrons for ion beam generation within a certain operating pressure;
b) an electron guide means for supplying a working gas for formation of plasma atmosphere and guiding into the working gas the electron flow generated from the electron emitter means;
c) an upper case for fixing the position of the electron guide means;
d) a deposit material having a certain area and disposed below the electron guide means, an exposed surface material of the deposit material being emitted and radiated in the form of ion when the working gas is transformed into a plasma atmosphere by charges guided by the electron emitter means and the electron guide means in a certain working gas atmosphere;
e) a cooling means placed below the deposit material for preventing overheat of the deposit material;
f) an electromagnetic field formation means placed below the cooling means for forming a certain magnitude of electromagnetic field such that electrons emitted from the electron emitter means is turned when guided by the electron guide means;
g) a lower case disposed facing the upper case for fixing the position of the deposit material, the cooling means and the electromagnetic field formation means; and
h) a power supply for retaining a certain magnitude of potential difference in the electron emitter means and the electron guide means and facilitating ion emission of the deposit material.

3. The system according to claim 2, wherein the electromagnetic field formation means employs a magnet or an electromagnet.

4. The system according to claim 2, wherein the cooling means includes a cooling jacket in which cooling water is circulated.

5. The system according to claim 2, wherein the electron guide means is divided into a first anode for guiding the working gas onto the surface of the deposit material and for guiding electron flow emitted from the electron emitter means, and a second anode for guiding the electron flow emitted from the electron emitter means and forming an ionization region; generally placed in the lateral face of the exposed face of the deposit material in the form of a side wall; and constructed to make an angle parallel to the direction of electromagnetic field generated in the electromagnetic field formation means and have an anode angle θ such that the electrons emitted from the electron emitter means can reach evenly over the entire face of the lateral wall.

6. The system according to claim 5, wherein the electron guide means is structured in the form of a rectangular frame or a circular frame.

7. The system according to claim 5, wherein the first anode includes: i) an upper portion having a first space into which a working gas is flown from outside; ii) an intermediate portion having a second space connected through a distribution hole for distributing the working gas flown into the firs space evenly over the whole area; and iii) a lower portion having a supply hole for discharging the working gas being filled in the second space.

8. The system according to claim 2, wherein the operating pressure is usually in a range of 10⁻⁵˜10⁻³ Torr., and typically 10⁻⁴ Torr.

9. The system according to claim 2, wherein the electron emitter means includes a filament having a certain length and area.

10. The system according to claim 2, wherein the electron emitter means have a desired spacing in a vertical direction to the centerline of the upper case and the lower case, a metal cathode case is provided with holes placed at desired regular intervals through which electrons are discharged along the centerline, and a filament for emitting thermal electrons is disposed inside the metallic cathode case filled with argon gas.

11. The system according to claim 2, wherein the electron emitter means have a desired spacing in a vertical direction to the centerline of the upper case and the lower case, a metal cathode case is provided with holes placed at desired regular intervals through which electrons are discharged along the centerline, and a hollow cathode for emitting electrons is disposed inside the metallic cathode case filled with argon gas.

12. The system according to claim 2, wherein the electron emitter means have a desired spacing in a vertical direction to the centerline of the upper case and the lower case, a metal cathode case is provided with holes placed at desired regular intervals through which electrons are discharged along the centerline, and an RF coil for emitting electrons is disposed inside the metallic cathode case filled with argon gas.

13. A direct ion beam deposition system using ion beam sputtering, the system comprising:
a) an electron emitter means for emitting initial electrons for ion beam generation within a certain operating pressure;
b) an electron guide means for supplying a working gas for formation of plasma atmosphere and guiding into the working gas the electron flow generated from the electron emitter means;
c) an upper case for fixing the position of the electron guide means;
d) an electromagnetic field formation means placed in the outer periphery of the upper case for forming a certain magnitude of electromagnetic field such that electrons emitted from the electron emitter means is turned when guided by the electron guide means;
e) a deposit material having a certain area and disposed below the electron guide means, a surface material of the deposit material being emitted and radiated in the form of ion when the working gas is transformed into a plasma atmosphere by charges guided by the electron emitter means and the electron guide means in a certain working gas atmosphere;
f) a cooling means placed below the deposit material for preventing overheat of the deposit material;
g) a lower case facing the upper case and for fixing the position of the deposit material and the cooling means; and
h) a power supply for retaining a certain magnitude of potential difference in the electron emitter means and the electron guide means and facilitating ion emission of the deposit material.

14. The system according to claim 13, wherein the electromagnetic field formation means employs a magnet or an electromagnet.

15. The system according to claim 13, wherein the cooling means includes a cooling jacket in which cooling water is circulated.

16. The system according to claim 13, wherein the electron guide means is divided into a first anode for guiding the working gas onto the surface of the deposit material and for guiding electron flow emitted from the electron emitter means, and a second anode for guiding the electron flow emitted from the electron emitter means and forming an ionization region; generally placed in the lateral face of the exposed face of the deposit material in the form of a side wall; constructed to make an angle parallel to the direction of electromagnetic field generated in the electromagnetic field formation means such that the electrons emitted from the electron emitter means can reach evenly over the entire face of the lateral wall; and structured such that the first anode has an area slightly smaller than that of the second anode.

17. The system according to claim 13, wherein the electron guide means is structured in the form of a rectangular frame or a circular frame.

18. The system according to claim 13, wherein the operating pressure is usually in a range of 10⁻⁵˜10⁻³ Torr., and typically 10⁻⁴ Torr.

19. The system according to claim 13, wherein the electron emitter means includes a filament having a certain length and area.

20. The system according to claim 13, wherein the electron emitter means have a desired spacing in a vertical direction to the centerline of the upper case and the lower case, a metal cathode case is provided with holes placed at desired regular intervals through which electrons are discharged along the centerline, and a filament for emitting thermal electrons is disposed inside the metallic cathode case filled with argon gas.

21. The system according to claim 13, wherein the electron emitter means have a desired spacing in a vertical direction to the centerline of the upper case and the lower case, a metal cathode case is provided with holes placed at desired regular intervals through which electrons are discharged along the centerline, and a hollow cathode for emitting electrons is disposed inside the metallic cathode case filled with argon gas.

22. The system according to claim 13, wherein the electron emitter means have a desired spacing in a vertical direction to the centerline of the upper case and the lower case, a metal cathode case is provided with holes placed at desired regular intervals through which electrons are discharged along the centerline, and an RF coil for emitting electrons is disposed inside the metallic cathode case filled with argon gas.
